(19) United States
(12) Patent Application Publication
(10) Pub. No.: US 2023/0386963 A1
(43) Pub. Date: Nov. 30, 2023

(54) POWER CONVERTER MODULE

(71) Applicant: TEXAS INSTRUMENTS INCORPORATED, DALLAS, TX (US)

(72) Inventors: WOOCHAN KIM, SAN JOSE, CA (US); Vivek Kishorechand Arora, San Jose, CA (US); Ninad Shahane, San Francisco, CA (US); Makoto Shibuya, Beppu City (JP)

(21) Appl. No.: 17/828,803

(22) Filed: May 31, 2022

(51) Int. Cl. H01L 23/373; H01L 23/66; H01L 23/12; H01L 23/498; H02M 3/155; H01L 25/18; H01L 23/00

(52) U.S. Cl. CPC H01L 23/3735; H01L 23/66; H01L 23/12; H01L 23/49811; H02M 3/155; H01L 25/18; H01L 24/48; H01L 2924/1033; H01L 2224/05567

(57) ABSTRACT

A power converter module includes a substrate having a first surface and a second surface that opposes the first surface. The power converter module includes a thick printed copper (TPC) substrate on the first surface of the substrate. The TPC substrate includes a first layer having TPC patterned on the first surface of the substrate and a second layer with dielectric patterned on the first layer. The TPC substrate includes a third layer having TPC patterned on the second layer. The power converter module includes power transistors mounted on the TPC substrate and a control integrated circuit (IC) chip mounted on the TPC substrate.

### TECHNICAL FIELD

This description relates to power converter modules.

### BACKGROUND

In electrical engineering, power conversion is the process of converting electric energy from one form to another. A power converter module is an electrical device that includes a power converter that can convert electrical energy. Some power converters convert direct current (DC) into alternating current (AC). Such power converters are sometimes referred to as a DC-to-AC power converter, or more simply as a power inverter. Some power converters convert AC into DC, such power converters are referred to as AC-to-DC power converters. Still other power converters, namely a DC-to-DC power converter converts a source of DC from one voltage level to another voltage level.

Gallium Nitride (GaN) has a relatively high electron mobility and saturation velocity that enables the employment of GaN for high-power and high-temperature microwave applications. High-power/high-frequency devices based on GaN include microwave radio-frequency power amplifiers (such as those used in high-speed wireless data transmission) and high-voltage switching devices for power grids. More particularly, GaN is employable to fabricate GaN field effect transistors (FETs). As compared with a metal-oxide semiconductor field effect transistor (MOSFET), the GaN FET has a lower drain to source resistance when the GaN FET is on (RDs(oN)). Also, a GaN FET has lower input capacitance than a MOSFET, such that the GaN FET has a faster on/off switching rate.

### SUMMARY

A first example relates to a power converter module that includes a substrate having a first surface and a second surface that opposes the first surface. The power converter module includes a thick printed copper (TPC) substrate on the first surface of the substrate. The TPC substrate includes a first layer having TPC patterned on the first surface of the substrate and a second layer having dielectric patterned on the first layer. The TPC substrate includes a third layer having TPC patterned on the second layer. The power converter module includes power transistors mounted on the TPC substrate and a control integrated circuit (IC) chip mounted on the TPC substrate.

A second example relates to a method for fabricating a power converter module. The method includes forming a TPC substrate on a surface of a substrate. The forming includes patterning a first layer for the TPC substrate on the surface of the substrate, and the first layer has TPC traces and/or TPC pads and patterning a second layer of the TPC substrate on the first layer, and the second layer includes a dielectric. The forming also includes patterning a third layer of the TPC substrate on the second layer, and the third layer has TPC traces and/or TPC pads. The method also includes mounting power transistors on the TPC substrate and mounting a control IC chip on the TPC substrate. The method further includes applying wire bonding to couple the power transistors and the control IC chip to the TPC substrate.

### BRIEF DESCRIPTION OF THE DRAWINGS

FIG. 1 illustrates a cross-section diagram of an example of a power converter module that includes a thick printed copper (TPC) substrate.

FIG. 2 illustrates a first stage of a method for forming a TPC substrate.

FIG. 3 illustrates a second stage of the method for forming a TPC substrate.

FIG. 4 illustrates a third stage of the method for forming a TPC substrate.

FIG. 5 illustrates a fourth stage of the method for forming a TPC substrate.

FIG. 6 illustrates a fifth stage of the method for forming a TPC substrate.

FIG. 7 illustrates an isometric view of a power converter module that includes a TPC substrate fabricated on a surface of a ceramic core.

FIG. 8 illustrates a simplified circuit diagram of a power converter module.

FIG. 9 illustrates a first stage of a method for fabricating a power converter module.

FIG. 10 illustrates a second stage of the method for fabricating a power converter module.

FIG. 11 illustrates a third stage of the method for fabricating a power converter module.

FIG. 12 Illustrates a fourth stage of the method for fabricating a power converter module.

FIG. 13 illustrates a fifth stage of the method for fabricating a power converter module.

FIG. 14 illustrates a sixth stage of the method for fabricating a power converter module.

FIG. 15 illustrates a seventh stage of the method for fabricating a power converter module.

FIG. 16 illustrates an eighth stage of the method for fabricating a power converter module.

FIG. 17 illustrates a ninth stage of the method for fabricating a power converter module.

FIG. 18 illustrates a tenth stage of the method for fabricating a power converter module.

FIG. 19 illustrates a flowchart of an example method for fabricating a power converter module.

FIG. 20 illustrates a flowchart of an example sub-method for forming a TPC substrate.

### DETAILED DESCRIPTION

This description relates to a power converter module that includes a thick printed copper (TPC) substrate. The power converter module is a multilevel switching power converter, such as a DC-to-DC converter or a DC-to-AC converter. The power converter module is fabricated with control IC chips that control power transistors to output high power. In various examples, the power transistors are implemented as gallium nitride (GaN) field effect transistors (FETs), but in other examples, other type of transistors, such as gallium oxide (GaO) or silicon carbide (SiC) transistors are also employable. In such examples, each of the control IC chips provides a corresponding control signal to a control node (e.g., a gate or base) of a subset of the power transistors. The power converter module is encased in a molding, such as plastic.

The TPC substrate is formed on a substrate of the power converter module. In some examples, the substrate is a ceramic core. In other examples, the substrate is a direct bonded copper (DBC) substrate. The TPC substrate is formed of layers of TCP (copper paste printed and fired) interleaved with layers of dielectric. More particularly, a first layer of the TPC substrate is formed by patterning TPC on the substrate of the power converter module. A second layer of the TPC substrate is formed by patterning dielectric on the first layer of the TPC substrate, and a third layer of the TPC substrate is formed by patterning a TPC on the second layer. In various examples, additional layers of dielectric and TPC are also included.

The TPC substrate includes pads for mounting components of the power converter module, such as the power transistors, the control IC chips and decoupling capacitors. The TPC substrate also includes TPC traces for efficient routing of signals. The efficient signal routing enabled by the TPC substrate allows for a reduction in size of the power converter module, as compared to a conventional power converter module that includes a printed circuit board (PCB). Also, the TPC substrate curtails parasitic inductance of a power loop in the power converter module thereby improving performance characteristics of the power converter module over conventional power converter modules that employ a PCB.

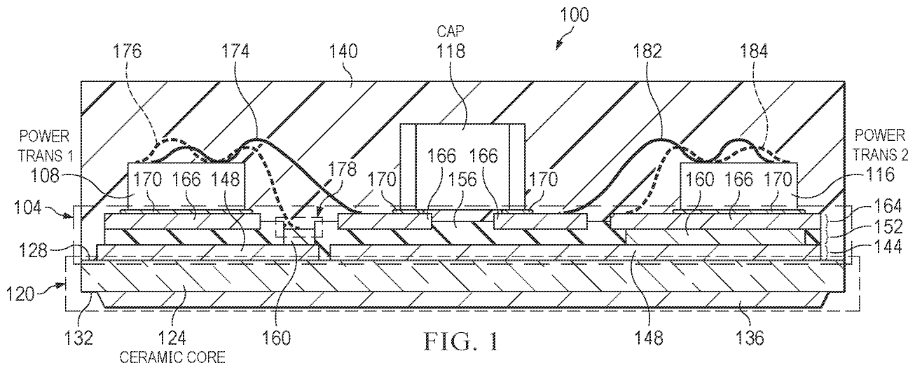

FIG. 1 illustrates a cross-section diagram of an example of a power converter module 100 that includes a thick printed copper (TPC) substrate 104. As one example, the power converter module 100 is a multilevel switching power converter. In some examples, the power converter module 100 is a multilevel DC-to-DC converter, such as a buck converter (a step-up converter) or a boost converter (a step-down converter). As another example, the power converter module 100 is a multilevel AC-to-DC converter, such as a half-bridge power converter or a full bridge power converter. In still other examples, the power converter module 100 is a multilevel DC-to-AC converter (e.g., an inverter). For the examples illustrated, it is presumed that the power converter module 100 is a DC-to-DC converter.

The power converter module 100 is fabricated with K number of control IC chips (hidden from view in FIG. 1) that control the first power transistor 108 and the second power transistor 116 to output high power, such as a range from about 100 volts (V) to about 700 V and a range of about 10 amperes (A) to about 150 A, where K is an integer greater than or equal to one. In the example illustrated, there are two power transistors, a first power transistor 108 and a second power transistor 116, but in other examples, there are more than two power transistors. In various examples, the first power transistor 108 and a second power transistor 116 are implemented as gallium nitride (GaN) field effect transistors (FETs), but in other examples, other type of transistors, such as gallium oxide (GaO) or silicon carbide (SiC) transistors are also employable. In such examples, each of the K number of control IC chips provides a corresponding control signal to a control node (e.g., a gate or base) of a subset of the power transistors. The power converter module 100 also includes a decoupling capacitor 118.

The TPC substrate 104 is mounted on a substrate 120. The substrate 120 includes a ceramic core 124. The ceramic core 124 has a first surface 128 and a second surface 132, and the first surface 128 opposes the second surface 132. In some examples, the TPC substrate 104 is mounted on the first surface 128 of the ceramic core 124, and a layer of copper 136 is mounted on the second surface 132 of the ceramic core 124. In other examples, the substrate 120 is a direct bonded copper (DBC) substrate, and the TPC substrate 104 is mounted on a copper layer of the DBC substrate. In some examples, a heat slug or heat sink is thermally coupled to the layer of copper 136.

The power converter module 100 is encased in a molding 140, such as plastic. In some examples, the power converter module 100 is mounted on a system bus. In such situations, the system bus is a communication bus for an external system, such as a communication bus of an automotive system.

The TPC substrate 104 is a multilayer substrate patterned to receive the first power transistor 108, the decoupling capacitor 118, the second power transistor 116 and the control IC chips of the power converter module 100. In the example illustrated, the TPC substrate 104 includes three (3) layers, but in other examples, there are more or less layers. A first layer 144 of the TPC substrate 104 is patterned on the first surface 128 of the ceramic core 124. The first layer 144 of the layer of the TPC substrate 104 is formed of TPC 148 (a copper paste) printed on the first surface 128 of the ceramic core 124 to form a pattern of TPC pads and/or traces and fired with high temperature (e.g., at 215 degrees Celsius or more).

A second layer 152 of the TPC substrate 104 is patterned on the first layer 144 of the TPC substrate 104. The second layer 152 of the TPC substrate 104 is formed with a layer of dielectric 156 that is patterned and etched. Moreover, TPC traces 160 are distributed within the second layer 152. The TPC traces 160 are formed by printing TPC on layers above the second layer 152, in a similar manner as the TPC 148 of the first layer 144 of the TPC substrate 104.

A third layer 164 of the TPC substrate 104 is patterned on the second layer 152 of the TPC substrate 104. The third layer 164 of the TPC substrate 104 is formed with TPC patterned on the second layer 152 to form TPC pads 166. In other examples, the third layer 164 also includes TPC traces. In some examples, the TPC traces 160 of the second layer 152 of the TPC substrate 104 provide a conductive path between the third layer 164 of the TPC substrate 104 and the first layer 144 of the TPC substrate 104. Stated differently, the TPC traces 160 of the second layer 152 of the TPC substrate 104 are vias.

In the example illustrated, the first power transistor 108, the second power transistor 116 and the decoupling capacitor 118 are mounted on the third layer 164 of the TPC substrate 104 with solder paste 170. Wire bonding is employed to couple the first power transistor 108 and the second power transistor 116 to the TPC substrate 104. More particularly, the first power transistor 108 is coupled to a TPC pad 166 of the third layer 164 of the TPC substrate 104 through a first wire bond 174. Also, the first power transistor 108 is coupled to a TPC trace 160 of the second layer 152 of the TPC substrate 104 with a second wire bond 176. In the example illustrated, the third layer 164 of the TPC substrate 104 includes a window 178 (alternatively referred to as a valley) that exposes the TPC trace 160 of the second layer 152 to the second wire bond 176 coupled to the first power transistor 108. The window 178 forms a void in the third layer 164 of the TPC substrate 104. In other examples, the window 178 is omitted. Also, a third wire bond 182 couples the second power transistor 116 to the decoupling capacitor 118, through a TPC pad 166 in the third layer 164 of the TPC substrate 104. Also, a fourth wire bond 184 couples the second power transistor 116 to a TPC pad 166 of the third layer 164 of the TPC substrate 104.

As noted above, the power converter module 100 is a multilevel power converter. In some such examples, each of the K number of control IC chips is dedicated to a particular switching level to control the power transistors (or some subset thereof) for intervals of a particular switching level operations of the power converter module 100. For instance, consider an example where the power converter module 100 has two (2) switching levels, a high side and a low side, a first subset of the power transistors are high side transistors and a second subset are low side transistors. In this situation, there are two control IC chips, namely a high side control IC chip and a low side control IC chip. Continuing with this example, in operation, the first control IC chip asserts a high side control signal during a high side switching level and de-asserts the high side control signal during the low side switching level. Assertion of the high side control signal turns on the first power transistor 108 (one of the high side transistors), causing the first power transistor to operate in the linear region or saturation region. Similarly, de-assertion of the high side control signal turns off the first power transistor 108, causing the first power transistor 108 to operate in the cutoff region. Also, in this example, the low side control IC chip asserts a low side control signal during a low side switching level and de-asserts the low side control signal during the high side switching level. Assertion of the low side control signal turns on the second power transistor 116 (one of the low side transistors), causing the second power transistor 116 to operate in the linear region or saturation region. Similarly, de-assertion of the low side control signal turns off the second subset of power transistors, causing the second subset of power transistors to operate in the cutoff region.

Continuing with this example, the low side control IC chip and the high side control IC chip are configured such that the high side control signal and the low side control signals are complementary signals. Accordingly, during operation, the power converter module 100 is configured such that the first power transistor 108 or the second power transistor 116 is turned on, and there is not a time that both the first power transistor 108 and the second power transistor 116 are both turned on.

More particularly, as noted above, the power converter module 100 is a multilevel switching power converter. The power converter module 100 is configured to be coupled to a load through leads to form a power loop. The switching loss (in volts), V_{SLoss} of the power converter module 100 throug the power loop is defined by Equation 1.

$${V}_{S L o s s} ( t ) = L * \frac{d i}{dt} \qquad Equation 1$$

Wherein:
   V_{SLoss}(t) is the switching loss, in volts (V) as a function of time;
   i is the current in a current loop of the power converter module;
   t is the time, in seconds; and
   L is the parasitic inductance of the power converter.

As demonstrated in Equation 1, the switching loss, V_{sLoss} increases as the parasitic inductance of the power converter module 100 increases. By forming the TPC substrate 104 directly on the substrate 120 (more particularly, on the first surface 128 of the ceramic core 124), the parasitic inductance, L of the power converter module 100 is curtailed. More specifically, the TPC substrate 104 curtails common source inductance that contributes the parasitic inductance, L by separating power and thermal with floating copper pads, such as the TPC pads 166 of the third layer 164 of the TPC substrate 104. In particular, the parasitic inductance, L of the power converter module 100 is about 100 nanohenries (nH) or less (e.g., about 0.87 nH). Unless otherwise stated, in this description, ‘about’ preceding a value means +/−10 percent of the stated value. Further, the power converter module 100 has a thermal resistance of about 1.02 degrees Celsius per watt (° C./W). Moreover, by situating the TPC substrate 104 directly on the first surface 128 of the ceramic core 124 (as opposed including a DBC substrate), the overall volume of the power converter module 100 is reduced by about 30%. Further, the TPC substrate 104 provides the TPC pads 166 for mounting components, thereby obviating the need for a PCB to mount such components.

Further, wire bonds, such as the second wire bond 176 coupled to the TPC trace 160 of the second layer 152 of the TPC substrate 104 through the window 178 in the third layer 164 of the TPC substrate 104 provides for efficient routing of wires, thereby reducing a size of the power loop, and curtailing an overall size of the power converter module 100.

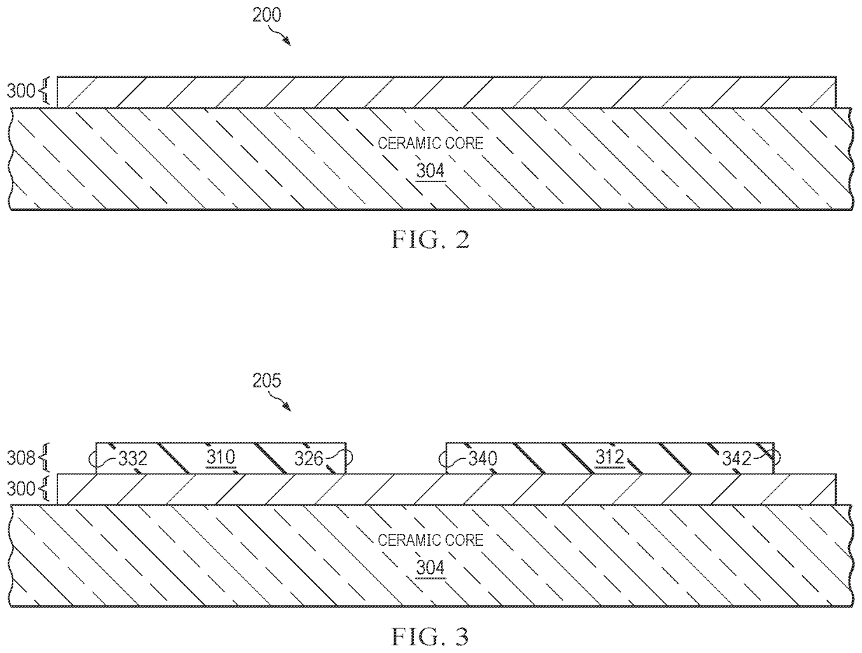

FIGS. 2-6 illustrate stages of a method for fabricating a TPC substrate, such as the TPC substrate 104 of FIG. 1 for a power converter module (e.g., the power converter module 100 of FIG. 1). The method of FIGS. 2-6 illustrate how TPC pads and traces are separated by dielectric. In FIGS. 2-6, copper paste with a thickness of about 30-300 micrometers (μm) is printed and fired in an iterative operation. Also, in FIGS. 2-6, a dielectric with a thickness of about 10-30 μm is formed between layers of TPC.

As illustrated in FIG. 2, at 200, in a first stage, a first TPC layer 300 is patterned on a surface of a ceramic core 304 (e.g., the ceramic core 124 of FIG. 1).

The first TPC layer 300 is printed and fired to adhere the first TPC layer 300 to the ceramic core 200. Although the example illustrated in FIG. 2 illustrates the first TPC layer 300 as being continuous, in some examples, the first TPC layer 300 is formed of TPC traces and/or TPC pads that are spaced apart (in an overhead view). As illustrated in FIG. 3, at 205 in a second stage, a first dielectric layer 308 is patterned on the first TPC layer 300. The first dielectric layer 308 includes a first dielectric pad 310 and a second dielectric pad 312. In some examples, to form the first dielectric pad 310 and the second dielectric pad 312, a sheet of dielectric is applied to the first TPC layer 300 and etched.

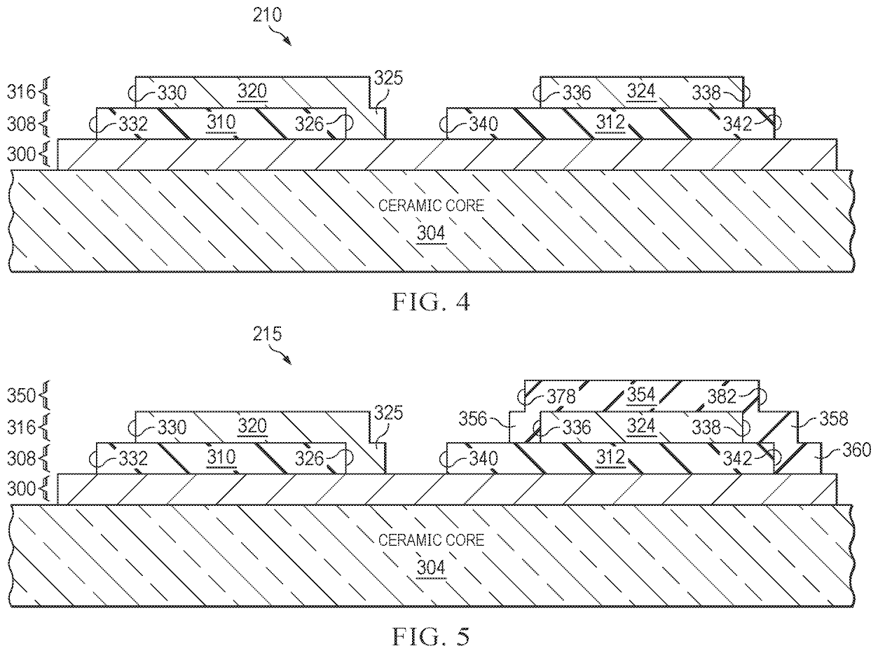

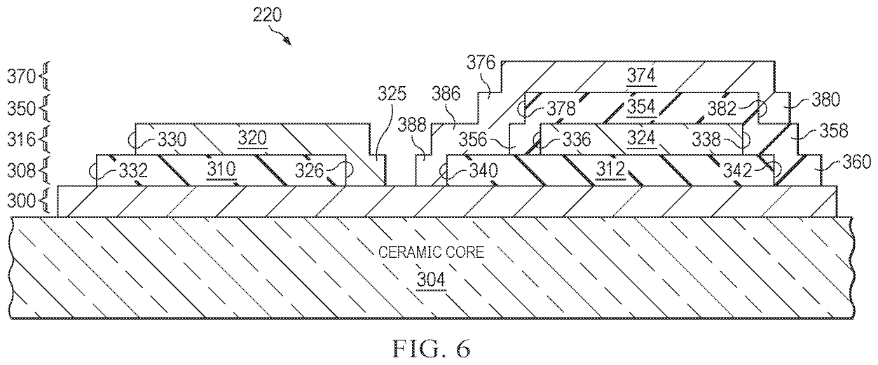

As illustrated in FIG. 4, at 210, in a third stage, a second TPC layer 316 is patterned on the first dielectric layer 308 with a printing and firing process. For illustrative purposes, in FIGS. 2-6 different layers employ different patterns to denote different applications of the TPC or the dielectric. The second TPC layer 316 includes a TPC pad 320 on the first dielectric pad 310 of the first dielectric layer 308 and a TPC trace 324 on the second dielectric pad 312 of the first dielectric layer 308.

Also, the TPC pad 320 includes a region 325 that extends beyond a first edge 326 of the first dielectric pad 310. In some examples, the region 325 (e.g., operating as a via) has a width of about 250 μm or more. Further, an edge 330 of the TPC pad 320 is spaced away from a second edge 332 of the first dielectric pad 310 by a distance of about 250 μm or more. Similarly, the TPC trace 324 has a first edge 336 and a second edge 338. The first edge 336 is about 650 μm or more from a first edge 340 of the second dielectric pad 312 and the second edge 338 is about 250 μm or more from a second edge 342 of the second dielectric pad 312.

As illustrated in FIG. 5, at 215, in a fourth stage, a second dielectric layer 350 is patterned on the second TPC layer 316. The second dielectric layer 350 includes a dielectric pad 354. The dielectric pad 354 includes a first region 356 that extends about 350 μm or more from the first edge 336 of the TPC trace 324 and a second region 358 that extends about 250 μm or more from the second edge 338 of the TPC trace 324. The dielectric pad 354 also includes a third region 360 that extends about 250 μm or more from the second edge 342 of the second dielectric pad 312.

As illustrated in FIG. 6, at 220, in a fifth stage, a third TPC layer 370 is patterned on the second dielectric layer 350. The third TPC layer 370 includes a TPC pad 374. A first region 376 of the third TPC layer 370 extends from a first edge 378 of the dielectric pad 354 and a second region 380 that extends away from a second edge 382 of the dielectric pad 354. The third TPC layer 370 also includes a third region 386 that extends about 250 μm or more from the first region 356 of the dielectric pad 354. Still further, the third TPC layer 370 includes a fourth region 388 that extends from the first edge 340 of the second dielectric pad 312. In this manner, the first region 376, the third region 386 and the fourth region 388 provide a conductive path between the first TPC layer 300 and the third TPC layer 370.

By employing the method illustrated in FIGS. 2-6, the TPC pad 320 and the TPC pad 374 are provided for mounting components for the power converter module, such as a control IC chip, a power transistor or a decoupling capacitor. Also, as illustrated, a relatively small spacing (e.g., 30-300 μm) is enabled between layers of the TPC substrate. This small spacing improves high frequency performance by reducing parasitic inductance and enables fine tuning of thermal performance of the power converter module. Further, as illustrated in FIGS. 2-6 depending on the application, in various examples, there are more or less layers of TPC and dielectric to form different configurations.

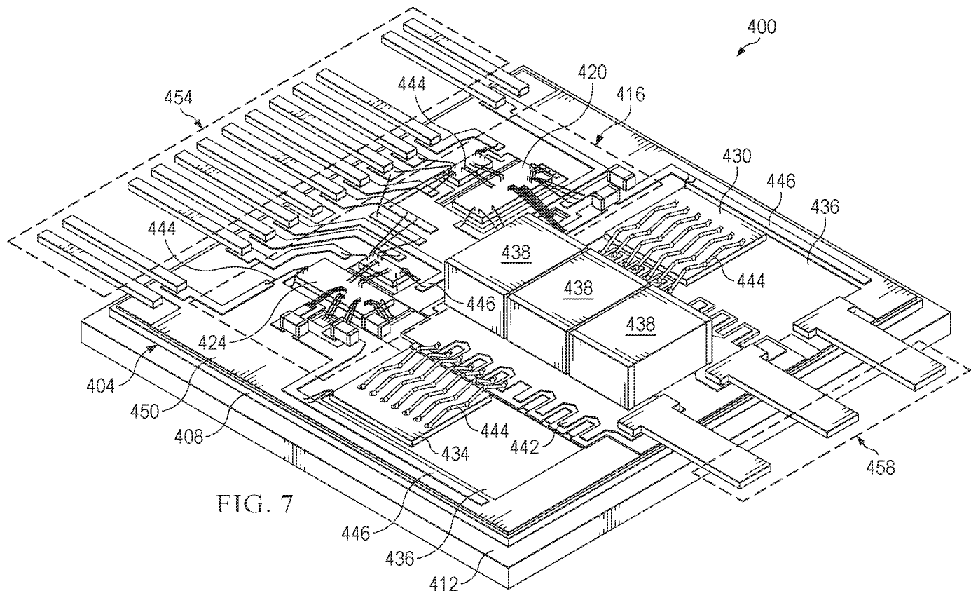

FIG. 7 illustrates an isometric view of a power converter module 400 that includes a TPC substrate 404 fabricated on a first surface of a ceramic core 408. A second surface of the ceramic core 408 is adhered to a heat slug 412 (e.g., a heat sink) formed of copper. The power converter module 400 is employable to implement the power converter module 100 of FIG. 1. Also, the TPC substrate 404 is employable to implement the TPC substrate 104 of FIG. 1 or the TPC substrate fabricated in FIGS. 2-6. The power converter module 400 is encased in a molding that has been removed for visibility.

The power converter module 400 includes a control region 416 formed in the TPC substrate 404. The control region 416 provides TPC pads, such as the TPC pad 320 and/or the TPC pad 374 of FIG. 6 for mounting components to control operations of the power converter module 400. More particularly, IC chips, such as a high side control IC chip 420 and a low side control IC chip 424 are mounted on the control region 416 of the TPC substrate.

The power converter module 400 includes power transistors. More specifically, the power converter module 400 includes a high side power transistor 430 (e.g., the first power transistor 108 of FIG. 1) and a low side power transistor 434 (e.g., the second power transistor 116 of FIG. 1). In the examples illustrated, there are two power transistors, namely the high side power transistor 430 and the low side power transistor 434. However, in other examples, there are more than two power transistors.

The high side power transistor 430 and the low side power transistor 434 are mounted on TPC pads 436 of the TPC substrate 404. The low side power transistor 434 is controlled by the low side control IC chip 424 of the control region 416, and the high side power transistor 430 is controlled by the high side control IC chip 420 of the control region 416. In some examples, the low side power transistor 434 and the high side power transistor 430 are implemented as GaN FETs, such as N-channel GaN FETs. In other examples, transistors such as SiC FETs or GaO FETs are employable as the low side power transistor 434 and the high side power transistor 430. In other examples, the low side power transistor 434 and the high side power transistor 430 are implemented as metal oxide semiconductor field effect transistors (MOSFETs). In still other examples, the low side power transistor 434 and the high side power transistor 430 are implemented as bipolar junction transistors (BJTs). The power converter module 400 also includes decoupling capacitors 438 that are employable to implement the decoupling capacitor 118 of FIG. 1. The decoupling capacitors 438 are mounted on a TPC pad 442 of the TPC substrate 404 of the power converter module 400. Wire bonds 444 (only some of which are labeled) are applied to couple components to the TPC substrate 404. These components include, but are not limited to the high side power transistor 430, the low side power transistor 434, the high side control IC chip 420 and the low side control IC chip 424.

As illustrated, throughout the TPC substrate 404, TPC traces 446 are included to provide conductive paths between components. Also, the dielectric 450 is included to provide insulation between the various instances of the TPC traces 446 and the TPC pads, such at the TPC pads 436 and the TPC pad 442. Further still, the power converter module 400 includes control pins 454 for controlling operations of the power converter module 400. The power converter module 400 also includes power pins 458 configured to couple the power converter module 400 to a load and to a power source.

As illustrated, the power converter module 400 is fabricated such that the TPC substrate 404 is mounted directly on the ceramic core 408, and components, such as the low side power transistor 434, the high side power transistor 430 and the decoupling capacitor 438 are mounted on TPC pads, such as the TPC pad 442. The TPC substrate 404 obviates the need for printed circuit boards (PCBs) or other features to mount circuit components, thereby reducing the size (volume) of the power converter module 400 and curtailing the parasitic inductance induced during operation.

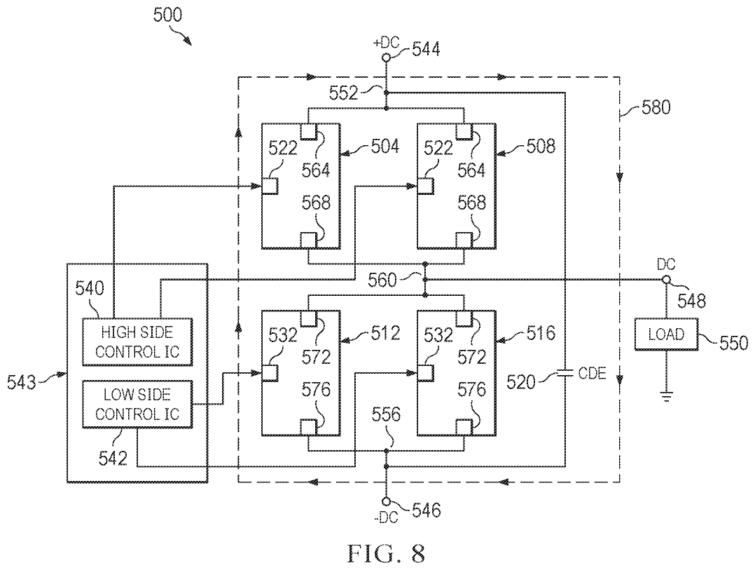

FIG. 8 illustrates a simplified circuit diagram of a power converter module 500. The power converter module 500 is illustrated as a DC-to-DC power converter. Moreover, the power converter module 500 is employable to implement the power converter module 100 of FIG. 1 and/or the power converter module 400 of FIG. 7. The components of the power converter module 500 are mounted on a TPC substrate, such as the TPC substrate 104 of FIG. 1 and/or the TPC substrate 404 of FIG. 7.

The power converter module 500 includes a first high side transistor 504 and a second high side transistor 508 mounted on the TPC substrate. The first high side transistor 504 and the second high side transistor 508 correspond to the high side power transistor 430 of FIG. 7. The power converter module 500 also includes a first low side transistor 512 and a second low side transistor 516 mounted on the TPC substrate. The first low side transistor 512 and the second low side transistor correspond to the low side power transistor 434 of FIG. 7. The power converter module 500 includes a decoupling capacitor 520 mounted on the TPC substrate that corresponds to one or more of the decoupling capacitors 438 of FIG. 7. In the example illustrated, it is presumed that the first high side transistor 504, the second high side transistor 508, the first low side transistor 512 and the second low side transistor 516 are GaN FETs. However, in other examples, other types of transistors, such as SiC FETs and GaO FETs, MOSFETS or BJTs are employable.

In the example illustrated, there are four (4) power transistors illustrated, namely, the first high side transistor 504, the second high side transistor 508, the first low side transistor 512 and the second low side transistor 516. However, in other examples, such as the example illustrated in FIG. 7, there is a single high side transistor and a single low side transistor. In still other examples, there are more than two high side transistors and more than two low side transistors.

The first high side transistor 504 and the second high side transistor 508 include a control node 522 (e.g., a gate or a base) that receives a high side control signal from a high side control IC chip 540. In some examples, the high side control signal provided to the control node 522 of the first high side transistor 504 and the control node 522 of the second high side transistor 508 are synchronous. Similarly, the first low side transistor 512 and the second low side transistor 516 include a control node 532 (e.g., a gate or a base) that receives a low side control signal from a low side control IC chip 542. In some examples, the low side control signal provided to the control node 532 of the first low side transistor 512 and the second low side transistor 516 are synchronous. Moreover, in some such examples, the high side control signal provided to the control node 522 of the first high side transistor 504 and the second high side transistor 508 are complements of the low side control signal provided to the control node 532 of the first low side transistor 512 and the second low side transistor 516.

The high side control IC chip 540 and the low side control IC chip 542 are mounted on a control region 543 (e.g., the control region 416 of FIG. 7) and are employable to implement control IC chips, such as the high side control IC chip 420 and the low side control IC chip 424 of FIG. 7. Accordingly, the high side control IC chip 540 and the low side control IC chip 542 are mounted on the TPC substrate.

The power converter module 500 includes a positive DC input terminal 544 and a negative DC input terminal 546. The power converter module 500 also includes a DC output terminal 548. The DC output terminal 548 is coupled to a load 550 that is external to the power converter module 500. The positive DC input terminal 544 is coupled to a first input node 552 of the power converter module 500. The negative DC input terminal 546 is coupled to a second input node 556 of the power converter module 500. Also, the DC output terminal 548 is coupled to an output node 560 of the power converter module 500.

A first node of the decoupling capacitor 520 is coupled to the first input node 552 of the power converter module 500 and a second node of the decoupling capacitor 520 is coupled to the second input node 556. The first high side transistor 504 and the second high side transistor 508 include an input node 564 (e.g., a drain or collector) that is coupled to the first input node 552. The first high side transistor 504 and the second high side transistor 508 include an output node 568 (e.g., a source or emitter) that is coupled to the output node 560.

The first low side transistor 512 and the second low side transistor 516 include an input node 572 (e.g., a drain or collector) that is coupled to the output node 560 of the power converter module 500. The first low side transistor 512 and the second low side transistor 516 include an output node 576 (e.g., a source or emitter) that is coupled to the negative DC input terminal 546.

In operation, current flows in a current path 580 that traverses the decoupling capacitor 520, the first high side transistor 504, the second high side transistor 508, the first low side transistor 512 and the second low side transistor 516. The current path 580 forms a loop, alternatively referred to as a current loop. Components forming the loop, including traces, the first high side transistor 504, the second high side transistor 508, the first low side transistor 512 and the second low side transistor 516 intermittently contribute to a parasitic inductance in the loop formed by the current path 580. Accordingly, by mounting the components directly on the TPC, which is formed on a ceramic core (e.g., the ceramic core 124 of FIG. 1 or the ceramic core 408 of FIG. 7), the parasitic inductance is curtailed, and the size of the loop formed by the current path 580 is reduced to improve operations of the power converter module 500.

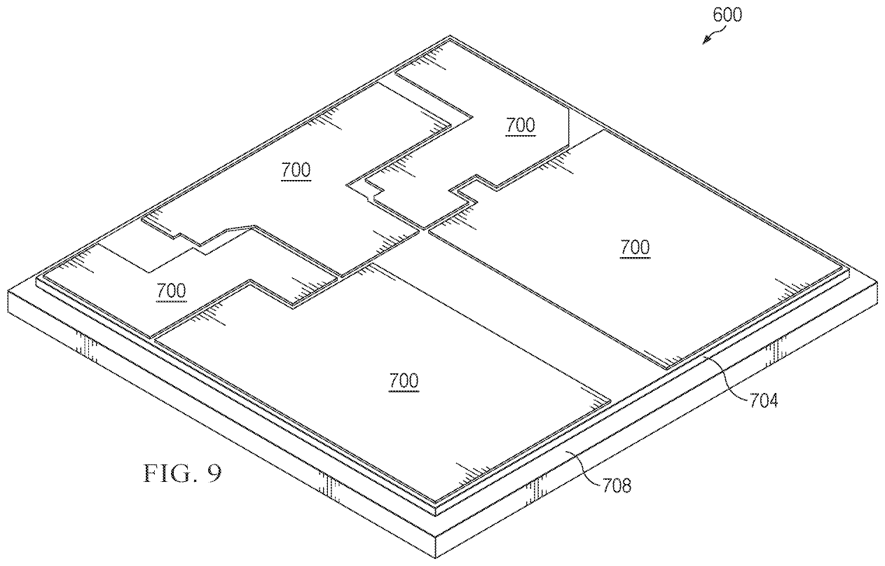

FIGS. 9-18 illustrate stages of a method for fabricating a power converter module, such as the power converter module 100 of FIG. 1 and/or the power converter module 400 of FIG. 9-18. The method of FIGS. 9-18 illustrates a TPC substrate is formed and employed in the power converter module. The TPC layers formed in FIGS. 9-18 are formed with copper paste that is printed and fired.

As illustrated in FIG. 9, at 600, in a first stage, a first TPC layer 700 is patterned on a first surface of a ceramic core 704. A heat slug 708 (e.g., a copper sheet) is adhered to a second surface of the ceramic core 704. The first TPC layer 700 forms copper pads.

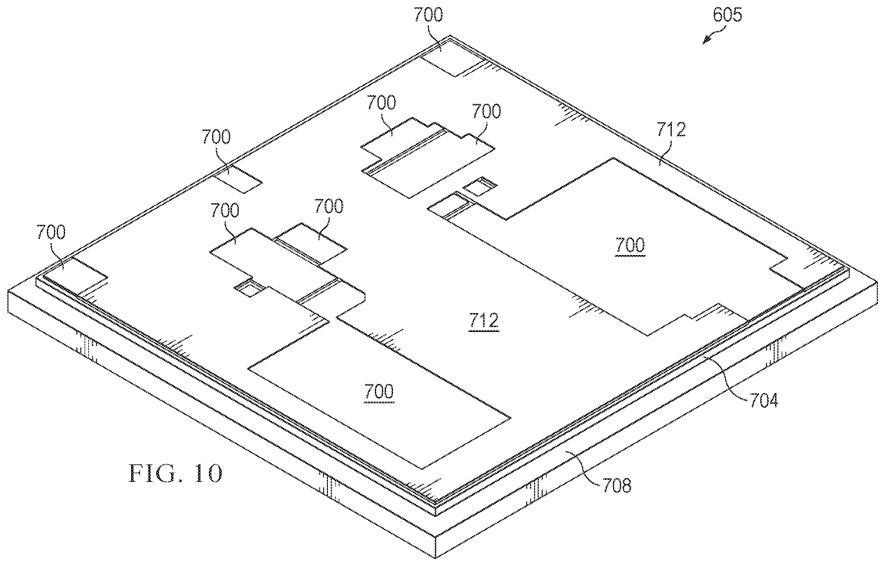

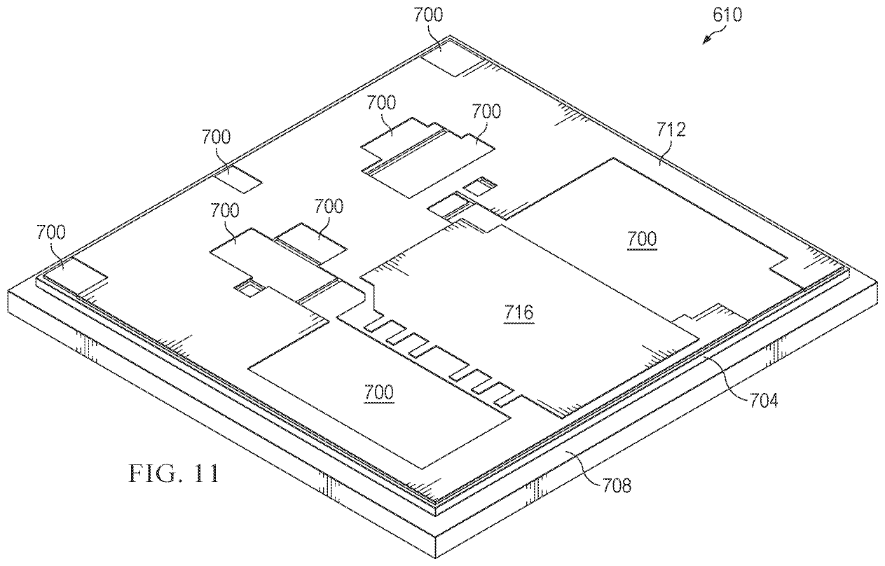

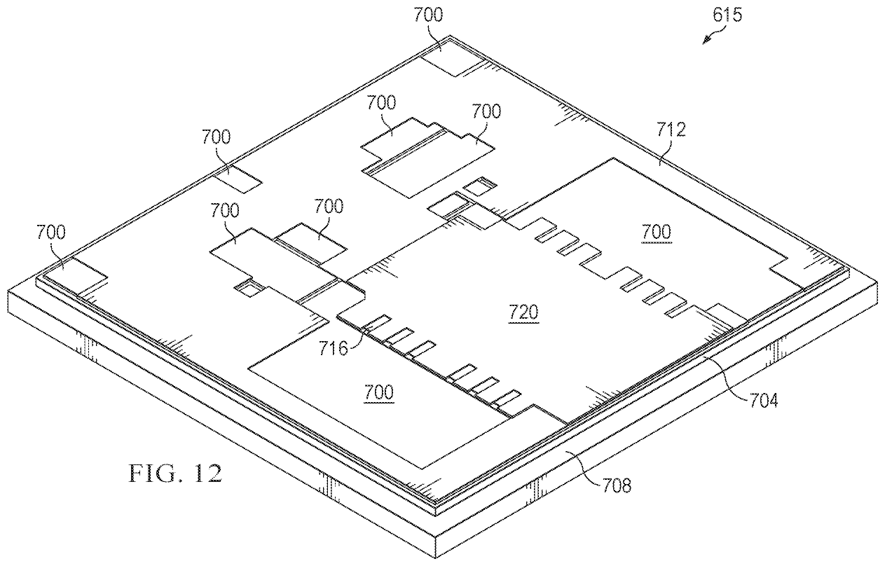

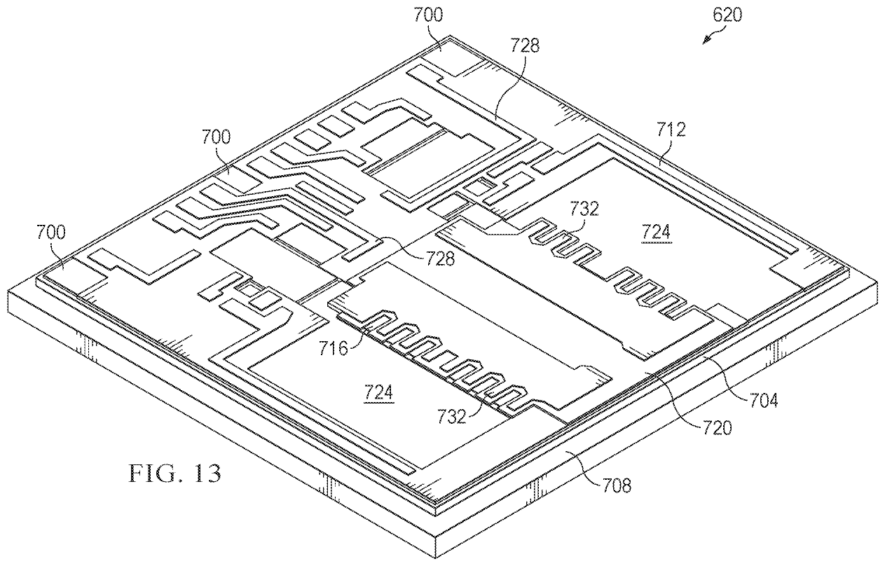

As illustrated in FIG. 10, in a second stage, at 605, a first dielectric layer 712 is patterned on the first TPC layer 700. As illustrated in FIG. 11, in a third stage, at 610, a second TPC layer 716 forming a TPC pad is formed on the first dielectric layer 712. As illustrated in FIG. 12, in a fourth stage, at 615, a second dielectric layer 720 (a dielectric pad) is patterned on the second TPC layer 716. As illustrated in FIG. 13, in a fifth stage, at 620, a third TPC layer 724 is patterned on the second dielectric layer 720 and the first dielectric layer 712. The third TPC layer 724 includes TPC traces 728 (only some of which are labeled), and TPC pads 732 (only some of which are labeled), and the TPC substrate is completed.

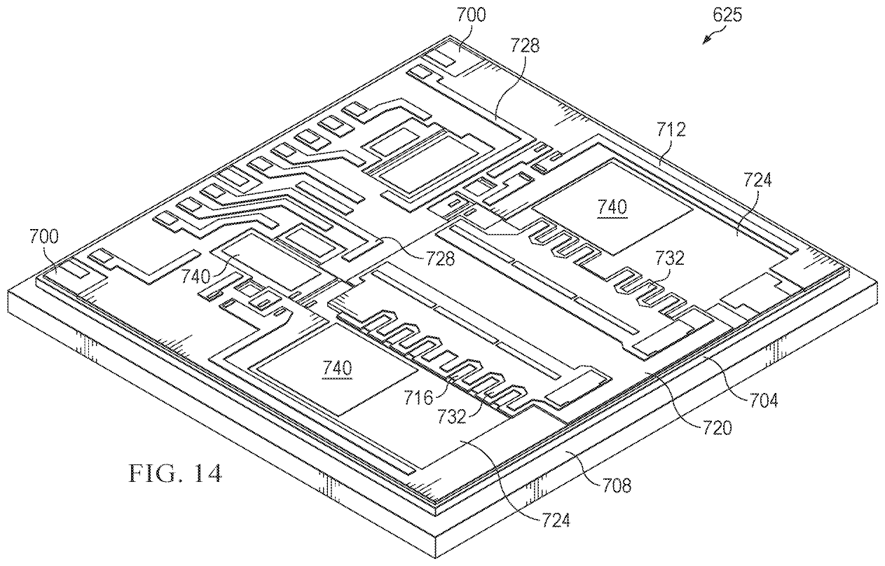

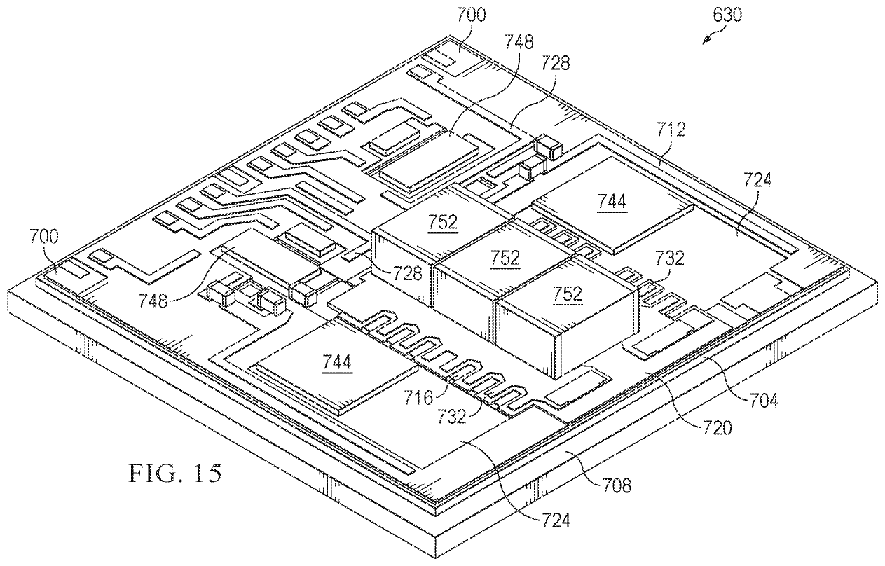

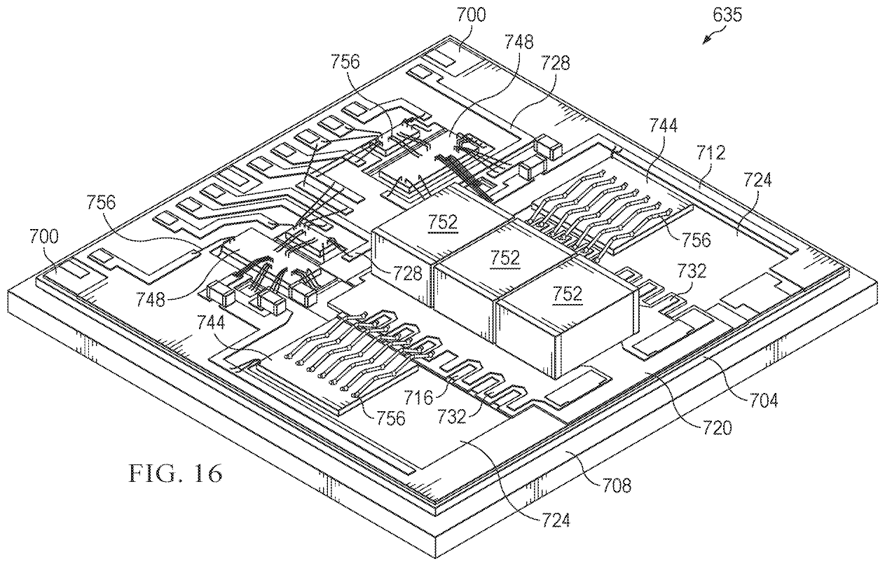

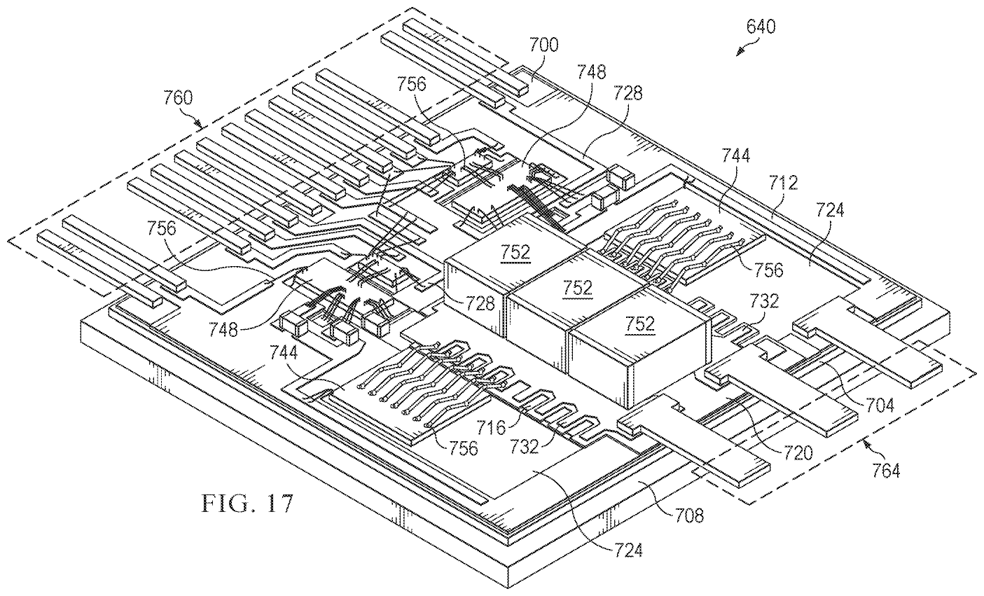

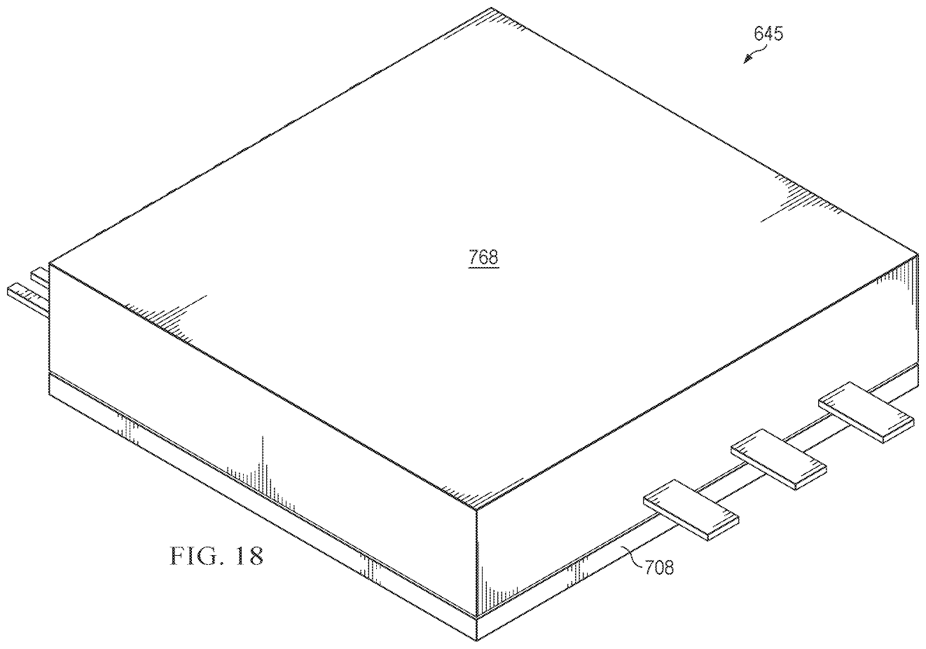

As illustrated in FIG. 14, in a sixth stage, at 625, solder patches 740 (only some of which are labeled) are applied to pads of the TPC substrate. As illustrated in FIG. 15, in a seventh stage, at 630, components are mounted on the TCP substrate. The components, include, but are not limited to power transistors 744 (e.g., the low side power transistor 434 and the high side power transistor 430 of FIG. 7), control IC chips 748 (e.g., the low side control IC chip 424 and the high side control IC chip 420 of FIG. 7), and decoupling capacitors 752 (e.g., the decoupling capacitors 438 of FIG. 7). As illustrated in FIG. 16, in an eighth stage, at 635, wire bonds 756 (only some of which are labeled) are attached to components to couple the components to the TPC substrate, such as one of the TPC pads 732. As illustrated in FIG. 17, in a ninth stage, at 640, control pins 760 (e.g., the control pins 454 of FIG. 7) and power pins 764 (e.g., the power pins 458 of FIG. 7) are mounted on the TPC substrate. As illustrated in FIG. 18, in an tenth stage, at 645, a molding 768 is applied to the first surface of the ceramic core 704 to circumscribe the TPC substrate and the installed components.

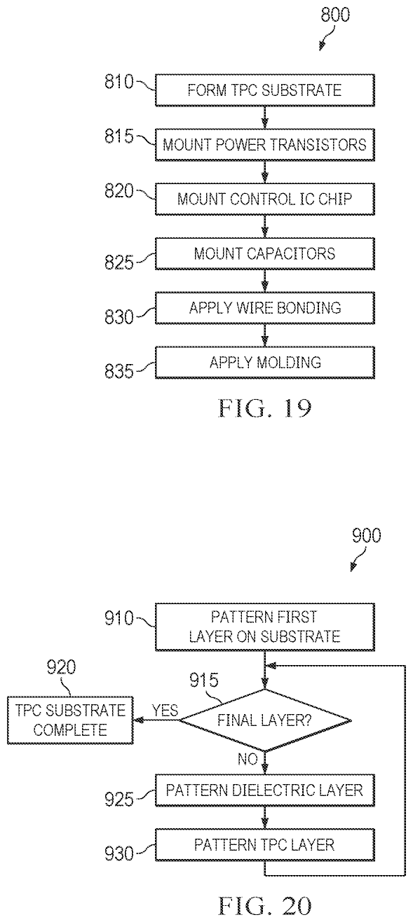

FIG. 19 illustrates a flowchart of an example method 800 for fabricating a power converter module, such as the power converter module 100 of FIG. 1 and/or the power converter module 400 of FIG. 7. At 810, a TPC substrate (e.g., the TPC substrate 104 of FIG. 1) is formed on a substrate. In some examples, the substrate is a ceramic core. In other examples, the substrate is a DBC substrate. The operations at 810 are executable in a sub-method.

At 815, power transistors (e.g., the first power transistor 108 and the second power transistor 116 of FIG. 1) are mounted on the TCP substrate. At 820, a control IC chip (e.g., the high side control IC chip 420 and/or the low side control IC chip 424 of FIG. 7) are mounted on the TPC substrate. At 825, decoupling capacitors (e.g., the decoupling capacitor 118 of FIG. 1) are mounted on the TPC substrate. At 830, wire bonds (e.g., the wire bonds 444 of FIG. 7) are applied to couple components (e.g., the power transistors and the control IC chips) to the TPC substrate. At 835, a molding (e.g., the molding 768) of FIG. 18 is applied to form the power converter module.

FIG. 20 illustrates a flowchart of an example sub-method 900 for forming a TPC substrate (e.g., the TPC substrate 104 of FIG. 1). The sub-method 900 is employable to implement the forming 810 of FIG. 19. At 910, a first layer (e.g., the first TPC layer 300 of FIG. 2) of the TPC substrate is patterned on a substrate, such as a substrate with a ceramic core. At 915, a determination is made as to whether a final layer of the TPC substrate has been formed. If the determination at 915 is positive (e.g., YES), the sub-method 900 proceeds to 920. If the determination at 915 is negative (e.g., NO), the sub-method 900 proceeds to 925. At 920, the TPC substrate is completed, and the sub-method 900 ends.

At 925, a dielectric layer (e.g., the first dielectric layer 308 of FIG. 3) is patterned on a topmost TPC layer. At 930, a next TPC layer (e.g., the second TPC layer 316 of FIG. 4) is patterned on the topmost dielectric layer, and the sub-method 900 returns to 915.

Modifications are possible in the described embodiments, and other embodiments are possible, within the scope of the claims.

What is claimed is:

1. A power converter module comprising:
a substrate having a first surface and a second surface that opposes the first surface;
a thick printed copper (TPC) substrate on the first surface of the substrate, the TPC substrate comprising:
a first layer comprising TPC patterned on the first surface of the substrate;
a second layer comprising dielectric patterned on the first layer; and
a third layer comprising TPC patterned on the second layer;
power transistors mounted on the TPC substrate; and
a control integrated circuit (IC) chip mounted on the TPC substrate.

2. The power converter module of claim 1, wherein the second layer of the TPC substrate further comprises:
a window formed of a void in the third layer that exposes a TPC trace or a TPC pad of the TPC patterned on the second layer that is coupled to a TPC trace or a TPC pad of the first layer.

3. The power converter module of claim 2, further comprising a wire bond coupled to the control IC chip and the TPC trace or TPC pad of the second layer.

4. The power converter module of claim 1, wherein the substrate is a ceramic core, and a layer of copper is adhered to the second surface of the ceramic core.

5. The power converter module of claim 1, wherein the substrate is a direct bonded copper substrate with a ceramic core.

6. The power converter module of claim 1, wherein the TPC substrate further comprises:
a fourth layer comprising dielectric patterned on the third layer; and
a fifth layer comprising TPC patterned on the fourth layer.

7. The power converter module of claim 1, wherein the power transistors are gallium nitride (GaN) field effect transistors (FETs).

8. The power converter module of claim 1, wherein the power converter module is a direct current (DC) to alternating current (AC) power converter module or a DC-to-DC power converter.

9. The power converter module of claim 1, further comprising a decoupling capacitor mounted on the TPC substrate.

10. The power converter module of claim 1, wherein the power transistors are configured to be coupled to a load.

11. The power converter module of claim 1 further comprising:
control pins mounted on the TPC substrate; and
power pins mounted on the TPC substrate.

12. The power converter module of claim 11, wherein a power loop comprising the power transistors has a parasitic inductance of about 100 nanohenries or less.

13. A method for fabricating a power converter module, the method comprising:
forming a thick printed copper (TPC) substrate on a surface of a substrate, wherein the forming comprises:
patterning a first layer for the TPC substrate on the surface of the substrate, wherein the first layer comprises TPC traces and/or TPC pads;
patterning a second layer of the TPC substrate on the first layer, wherein the second layer comprises a dielectric;
patterning a third layer of the TPC substrate on the second layer, wherein the third layer comprises TPC traces and/or TPC pads;
mounting power transistors on the TPC substrate;
mounting a control IC chip on the TPC substrate; and
applying wire bonding to couple the power transistors and the control IC chip to the TPC substrate.

14. The method of claim 13, further comprising mounting a decoupling capacitor on the TPC substrate.

15. The method of claim 13, wherein the wire bonding extends from a surface of the control IC chip through a window in the third layer to a TPC pad or TPC trace in the second layer of the TPC substrate.

16. The method of claim 13, wherein the power transistors are gallium nitride (GaN) field effect transistors (FETs).

17. The method of claim 13, wherein the power converter module is a direct current (DC) to alternating current (AC) power converter module or a DC-to-DC power converter.

18. The method of claim 13, further comprising, mounting control pins and power pins on the TPC substrate.

19. The method of claim 13, wherein the surface of the substrate is a first surface, and the substrate is a ceramic core, and a layer of copper is adhered to a second surface of the ceramic core.

20. The method of claim 13, wherein the substrate is a direct bonded copper substrate with a ceramic core.
